(19) United States
(12) Patent Application Publication
(10) Pub. No.: US 2001/0046566 A1
(43) Pub. Date: Nov. 29, 2001

(54) Apparatus and method for direct current plasma immersion ion implantation

(76) Inventors: Paul K. Chu, Kowloon (HK); Dixon T.K. Kwok, Kowloon (HK); Xuchu Zeng, Kowloon (HK)

Correspondence Address: MERCHANT & GOULD PC, P.O. BOX 2903, MINNEAPOLIS, MN, 55402-0903, US

(21) Appl. No.: 09/815,955

(22) Filed: Mar. 23, 2001

Related U.S. Application Data
(60) Provisional application No. 60/191,710, filed on Mar. 23, 2000.

(51) Int. Cl. H01J 7/24; H05B 31/26; C23C 14/00

(52) U.S. Cl. 427/523; 315/111.81

(57) ABSTRACT

An apparatus and method are disclosed for a low-pressure steady-state direct current or long-pulse mode of plasma immersion ion implantation. A conducting grid is located between the wafer stage and the supply of plasma. The supply of plasma may be controlled through a variable aperture in which is provided the conducting grid.

### FIELD OF THE INVENTION

This invention relates to a method and apparatus for plasma immersion ion implantation (PIII), and in particular to such an apparatus and method for DC or long pulse length quasi-DC techniques.

### BACKGROUND OF THE INVENTION

Plasma immersion ion implantation (PIII) is a versatile materials fabrication and surface treatment technique. The non-line of sight advantages of PIII mean that is a very useful technique for enhancing the properties and performance of large and irregular-shaped industrial components. For example, PIII has been applied to synthesise silicon-on-insulator (SOI) substrates for low-power, high-speed complementary metal oxide silicon (CMOS) microelectronic components. In the fabrication of SOI, PIII is an efficient and economical process for implantation of high doses of hydrogen into a silicon wafer, and as the implantation time is independent of the wafer diameter, it is a very appealing technique for larger wafers. However, in traditional PIII the entire surface of the wafer is implanted, even though for planar samples such as silicon wafers the only surface of importance is the front surface, and ions implanted into other areas such as the sides and bottom, and also ions implanted in the wafer table or chuck, are wasted and can cause deleterious effects such as sputtered metallic contamination from the wafer table or chuck. In addition high-voltage PIII (ie above 100 kV) is very difficult because under a high sample bias voltage the plasma sheath is very thick thereby requiring a large vacuum chamber or high-density plasma, and the required high-voltage power modulator is also prohibitively expensive.

### PRIOR ART

PIII differs from conventional beam-line implantation in several aspects. In beam-line ion implantation, the ions are accelerated by the electric field and filtered according to their mass-to-charge ratios. In PIII, however, the target is immersed in the plasma and is biased by a series of negative voltage pulses. When the target is negatively biased, electrons are repelled away leaving a sheath of heavy positive ions. An electric field builds up between the sheath boundary and target surface, and ions are accelerated towards the target. In order to maintain a continuous flow of ions, the ion sheath expands until the end of the negative pulse.

There are a number of considerations and potential drawbacks with using negative voltage pulses in PIII applications. When a negative high voltage pulse is imposed, the vacuum chamber, sheath, and electrical circuit inherently induce an equivalent capacitive load on the modulator thereby giving rise to a displacement current. The displacement current generates extra heating to the wafer and wafer stage or chuck. Deleterious metal impurities can diffuse from the contact interface to the wafer and can be subsequently driven into the wafer at higher temperature. This means that cooling of the wafer is sometimes necessary. Furthermore, during the short but nonetheless finite rise and fall times of each voltage pulse, the ion acceleration energy is reduced, resulting in a low energy component in the implant distribution.

To mitigate these effects, it would be desirable for the pulse width to be elongated to 100 μs or longer. More ideally still the implantation may be carried out in direct current (DC) mode, ie implanting the wafer from a steady-state Child-Langmuir law sheath. However DC operation at high-voltages requires a large vacuum chamber because at high implantation voltages the plasma will be extinguished if the sheath touches the wall of the vacuum chamber. This can happen, for example, when the vacuum chamber (and in particular the distance between the target and the plasma source) is too small, the plasma density is too low, or the voltage pulse is too long.

Since the chamber size is usually limited, in order to maintain a long pulse the plasma density must be increased, but there are a number of technical difficulties that make such a system unrealistic at the low pressure needed for mono-energetic implantation (ie ion mean free path is larger than the sheath thickness). These constraints, together with the limitations on the power modulator, impose a practical maximum voltage in PIII techniques that make PIII unsuitable for a number of potential applications, such as for example the fabrication of thick SIMOX (separation by implantation of oxygen) materials. It should also be noted that the local impact angle in conventional PIII depends on the shape of the target.

### SUMMARY OF THE INVENTION

According to the invention there is provided apparatus for direct current plasma ion implantation, comprising: (a) a vacuum chamber, (b) an ion/plasma source, (c) means for supporting a target in said chamber, (d) means for applying an electrical potential to said target supporting means, and (e) a conducting grid being located between said target supporting means and said ion/plasma source dividing said chamber into two parts.

Preferably the conducting grid is grounded and said target supporting means is maintained at a negative potential. Alternatively the conducting grid may be maintained at a first negative potential and the target supporting means is maintained at a second negative potential, the target supporting means being maintained at a negative potential relative to the conducting grid.

In a preferred embodiment the vacuum chamber has a disk-like shape, and the dimensions of the chamber have the ratio r:R:H:D=1:4:2.5:2 where:

r=radius of the target

R=radius of the vacuum chamber

H=the distance between the target and the grid, and

D=the thickness of the target.

The grid is preferably made of a material compatible with an intended target, for example if the intended target is a silicon wafer the grid may be made of a silicon mesh.

Preferably means are provided for varying the distance between the target supporting means and the conducting grid. This allows the implantation properties to be varied.

In preferred embodiments of the invention the vacuum chamber is divided into two parts by a wall of said chamber, the wall being provided with an aperture allowing plasma formed in a first of said two part to diffuse into the second of said two parts containing said target, and wherein the conducting grid is provided across the aperture. More preferably still the aperture has a variable size.

### BRIEF DESCRIPTION OF DRAWINGS

Some embodiments of the invention will now be described by way of example and with reference to the accompanying drawings, in which:

FIG. 1 is a schematic view of apparatus according to a first embodiment of the invention,

FIGS. 2(a)-(d) show the ion paths of oxygen ions implanted from the grid to the wafer stage at −70 kV bias voltage,

FIG. 3 is a schematic view of apparatus according to a second embodiment of the invention,

FIGS. 4 to 6 are I-V curves for respectively hydrogen, nitrogen and argon in the embodiment of FIG. 3,

FIGS. 7 and 8 are Rutherford back scattering spectroscopy results for an example of the embodiment of FIG. 3 using argon,

FIG. 9 is an argon depth profile of a wafer implanted by argon using the embodiment of FIG. 3,

FIG. 10 shows schematically an apparatus according to a third embodiment of the invention,

FIG. 11 shows typical voltage and current waveforms for the embodiment of FIG. 10,

FIG. 12 shows the relationship between pulse current and electron saturation current in the embodiment of FIG. 10,

FIG. 13 is an optical micrograph of a silicon wafer implanted with hydrogen according to the third embodiment of the invention and

FIG. 14 shows the implantation at three different pulse durations.

### DETAILED DESCRIPTION OF PREFERRED EMBODIMENTS

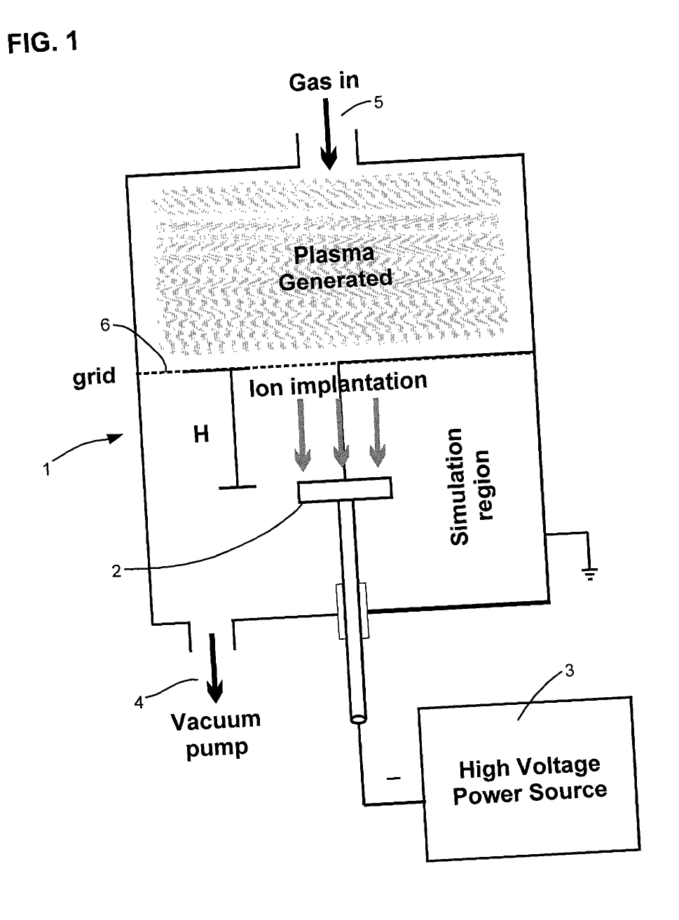

Referring firstly to FIG. 1 there is shown schematically a first embodiment of the present invention. In this embodiment there is provided apparatus for direct current or long pulse PIII comprising a vacuum chamber 1. Within the vacuum chamber 1 there is provided a wafer table, support or chuck 2 for holding a wafer, for example a silicon wafer that is to be ion implanted. The wafer table 2 is connected to a high voltage power source 3 so that the wafer table 2 can be negatively biased. If the sample is a conducting or at least semiconducting planar sample the potential on the sample surface will be the same as that applied to the wafer table. The vacuum chamber 1 may be maintained at any desired low pressure by a vacuum pump 4. The vacuum chamber is also provided with a source 5 for gas to form the plasma. The plasma in this embodiment is formed by a radio-frequency inductively-coupled plasma (RF-ICP) technique.

The vacuum chamber 1 is divided into two parts by means of a conducting grid 6. The conducting grid 6 is formed of a mesh of conducting material and extends transversely across the vacuum chamber 1 so as to divide the chamber 1 such that the plasma source 5 and the wafer table 1 are located on opposite sides of the grid 6. The conducting grid 6 is preferably formed of a material that is compatible with the wafer (for example it might be a silicon coated mesh if the wafer is silicon) so as to avoid contamination. The conducting grid is grounded and divides the vacuum chamber into two parts. In the lower part containing the wafer, a strong electric field is formed between the negatively biased wafer table and the conducting grid. The upper part of the vacuum chamber between the conducting grid and the plasma source confines the plasma since the conducting grid stops the expansion of the ion sheath from the bottom of the chamber. In this way, a continuous low-pressure discharge may be maintained in the part of the chamber above the grid. Positive ions diffuse from the plasma through the grid into the lower part of the chamber and are then accelerated towards the wafer by the electric field and are implanted in the wafer. The conducting grid is preferably grounded, but may also be at a slight negative potential, though of course it must be less negative than the wafer stage. A further possibility is that the grid may even be given a small positive potential. Providing the grid with a small potential may provide for better ion focussing.

By performing particle-in-cell (PIC) numerical simulation, it can be observed that the ion paths do not depend on the applied voltage and ion mass. The ion paths are, however, sensitive to the initial diffusion velocity and the relative size of the chamber and the placement of the wafer. The embodiment of FIG. 1 may be modeled and simulated as follows.

The potential above the grid is at plasma voltage, whereas the potential of the part below the grid is influenced by the wafer stage applied voltage and can be solved by Laplace's equation in cylindrical coordinates:

$$\frac{{\partial }^{2} φ}{\partial {r}^{2}} + \frac{1}{r} \frac{\partial φ}{\partial r} + \frac{{\partial }^{2} φ}{\partial {z}^{2}} = 0 \qquad ( 1 )$$

where φ is the potential, r is the radial distance from the center, and z is the longitudinal distance. It is assumed that the space charge density is approximately equal to zero in the lower part during the DC mode. In the ideal situation, the electric field is built up before the generation of the plasma. That is, there is initially no plasma inside the lower part. The secondary electrons created during the implantation are immediately absorbed by the chamber walls and grounded grid as they are light and energetic. The diffusion rate relative to the electric field strength is too small to gather the ions and change the potential. Eq. 1 can be solved by the finite difference method. Initially a sheet of particles/ions is rested just below the grid in the simulation region shown in FIG. 1. The lower part of the chamber has a cylindrical symmetry and the simulation region can be reduced to a plane shown in FIG. 1. The particles will be pulled by the electric field and their trajectories are followed until they hit the wafer stage. The motions of the ions are governed by Newton's equations of motion in cylindrical coordinates:

$$\begin{matrix}{v}_{i}^{r} ( f ) = {v}_{i}^{r} ( I ) - \frac{q}{M} \frac{\partial φ}{\partial r} t & \text{(2a)} \\ {v}_{i}^{z} ( f ) = {v}_{i}^{z} ( I ) - \frac{q}{M} \frac{\partial φ}{\partial z} t & \text{(2b)} \\ Δ r = {v}_{i}^{r} ( I ) t - \frac{1}{2} \frac{q}{M} \frac{\partial φ}{\partial r} {t}^{2} & \text{(3a)} \\ Δ z = {v}_{i}^{z} ( I ) t - \frac{1}{2} \frac{q}{M} \frac{\partial φ}{\partial r} {t}^{2} & \text{(3b)}\end{matrix}$$

where M is the ion mass, q is the ion charge, and vᵢ^{r}(f), vᵢ^{r}(I), vᵢ^{z}(f), and, vₜ^{z}(I) are the initial and final velocities of the ion at time step t, respectively. The internal dimensions of the chamber may be as follows (typical dimensions for a conventional PIII instrument): The wafer stage, 0.056 m in thickness and 0.081 m in radius, is supported by a thin metal rod 0.3 m in length and 0.004 m in radius connected to the high power voltage supply. The vacuum chamber radius is 0.381 m, and the distance between the top of the wafer stage and the grid H can be varied.

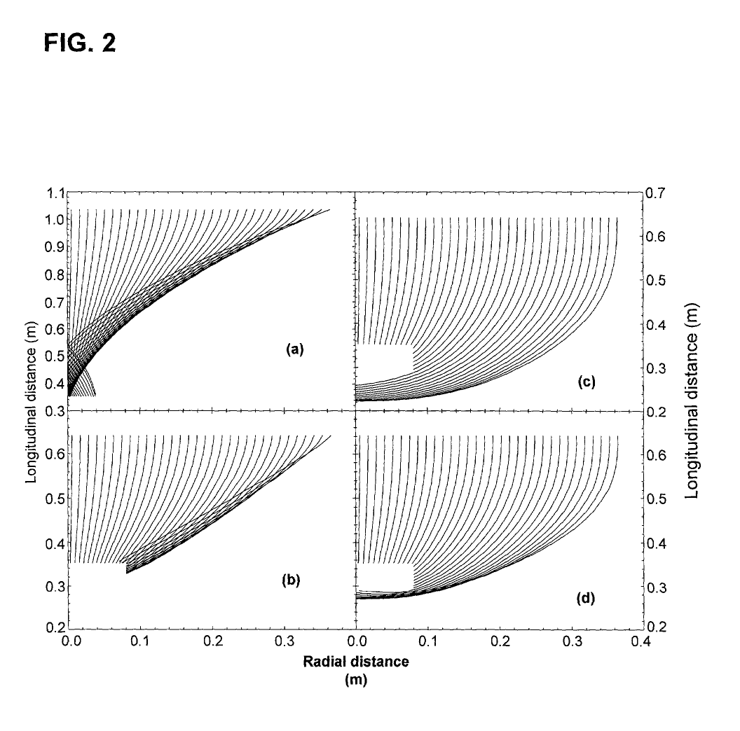

The simulation shows that the ion paths will not change with the negative voltage applied to the wafer stage, mass, and charged states of the ions, provided that their initial velocity is small compared to the electric field strength. The ion path of O⁺ particles at H=70 cm and H=30 cm are depicted in FIGS. 2a and 2b. The applied voltage is −70 kV and the initial velocity of the particles is zero. FIG. 2a reveals that some of the particles will pass through the mid-plane and get implanted at the other half of the wafer stage. At H=70 cm, the ions will focus onto the center of the wafer stage. The ion path is determined by the velocity vector which in turn changes with the acceleration vector created by the force field in space. As shown in Eq. 2, the acceleration vector can be written as:

$$\begin{matrix}ρ \\ a\end{matrix} = ( - \frac{q}{M} \frac{\partial φ}{\partial r} ) \hat{r} + ( - \frac{q}{M} \frac{\partial φ}{\partial z} ) \hat{k} \qquad \text{(4)}$$

The directional angle θ of the vector [symbol] is:

$$θ = {tan}^{- 1} ( \frac{- \frac{q}{M} \frac{\partial φ}{\partial z}}{- \frac{q}{M} \frac{\partial φ}{\partial r}} ) = {tan}^{- 1 } ( \frac{ \frac{\partial φ}{\partial z}}{ \frac{\partial φ}{\partial r}} ) \qquad \text{(5a)}$$

This shows that the directional angle does not depend on the charge state and mass of the ions. The ratio of the partial differential of the scalar potential φ along the radial and longitudinal directions remains constant for different values of φ. It follows that the directional angle θ of the accelerating force field is totally determined by the local field structure of the lower part of the chamber. Therefore, if the ions are placed at the same starting position with zero initial velocity, they will pass through the same local field path. The amplitude A of the acceleration indeed will vary with the charge state, ion mass, and applied voltage:

$$A = \frac{q}{M} \sqrt{{( \frac{\partial φ}{\partial r} )}^{2} + {( \frac{\partial φ}{\partial z} )}^{2}} \qquad \text{(5b)}$$

Hence, by varying the charge state of the ion and applied voltage, the impact energy can be altered, and by varying the ion mass, the final velocity of the ion will be changed. However, if the ions have a large initial drift velocity compared to the maximum velocity created by the applied voltage, they will pass through a different local field structure. In this situation, the ion paths will vary with the charge state, ion mass, and applied voltage. The ion path of the O⁺ and O²⁺ particles with initial downward drift velocity 2.4468×10⁵ m/sec (equal to 5 keV impact energy of oxygen ions) are displayed in FIGS. 2c and 2d for H=30 cm and applied voltage 32 −70 kV. Part of the ions have passed through the wafer stage and are implanted into the supporting rod.

Usually, in PIII, the ions are at room temperature, i.e., 0.026 eV, and the drift velocity is very small compared with the applied voltage. The working gas pressure is less than 1 mTorr and the gas is weakly ionized. The pressure gradient is small. Therefore, the ion path of different ions is similar.

The dose and energy uniformity along the implanted wafer are important issues for PIII in semiconductor applications. Here, conventional PIII can be compared to the DC method of the present invention. As mentioned before, in PIII, there are a large number of low impact energy ions introduced into the wafer during the rise and fall times of each negative voltage pulse. On the other hand, in the DC mode, the ion impact energy is constant since the ions are accelerated directly from the grid to the wafer stage. The uniformity of the ion dose on the wafer depends on two factors: the uniformity of the incident ion current and impact angle.

Previously it has been shown that the PIII ion dose is higher at the edge of the wafer stage when the impact angle is off normal up to 45°. Therefore, although the depth profile is shallower at the edge, the ion dose is higher. In the DC mode of this embodiment of the present invention, the implantation area is totally determined by the ratio of the radius of wafer stage r, the radius of the vacuum chamber R, the distance between the wafer stage and grid H, and thickness of the wafer stage D. The projected area from the grid to the wafer stage determines the incident dose into the wafer. The smaller H is, the closer is the ratio of the projected area to the implanted area to 1 and the better is the incident dose uniformity. However, the shorter the distance between the anode (grid) and cathode (wafer stage), the higher is the electric field that may lead to breakdown at high implantation voltage. The impact angle at the edge can be made normal by changing the thickness of the wafer stage. A thicker wafer stage can smooth out the electric field at the edge. In PIII, the ions are accelerated from the ion sheath and the impact angle is dominated by the spherical shape of the ion sheath. The results show that the retained dose and impact energy in the DC mode of this embodiment of the invention can be made much more uniform by choosing the suitable internal dimensions of the lower part. The best ratio is r:R:H:D=1:4:2.5:2. That is, a disk shape chamber instead of the conventional cylindrical chamber is preferred, though a cylindrical chamber may nevertheless also be employed.

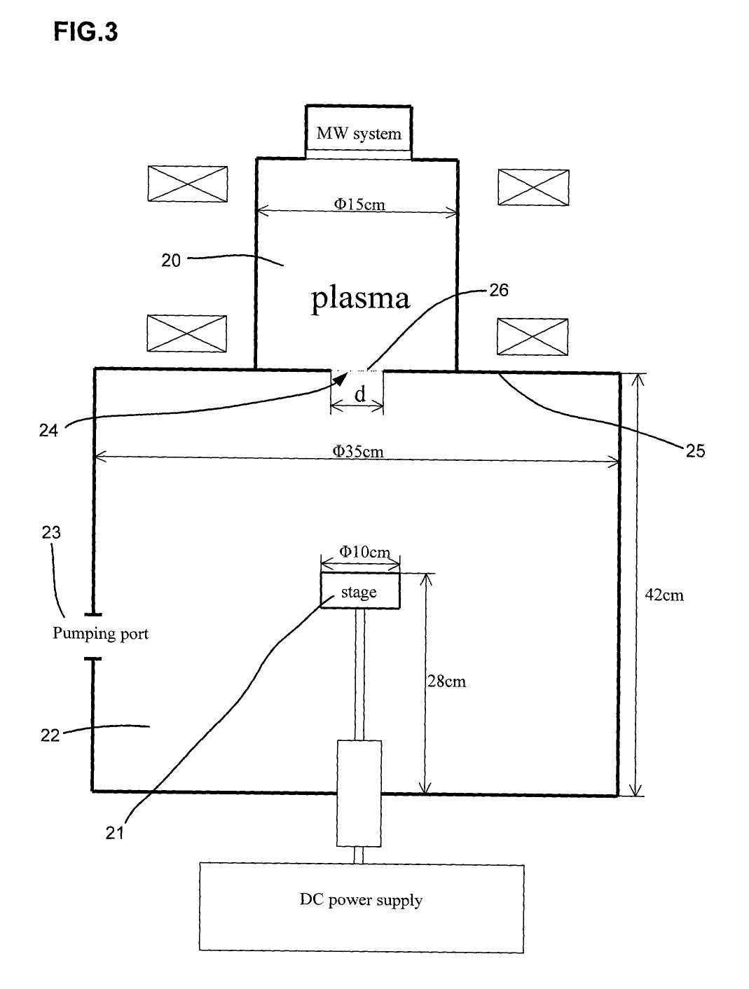

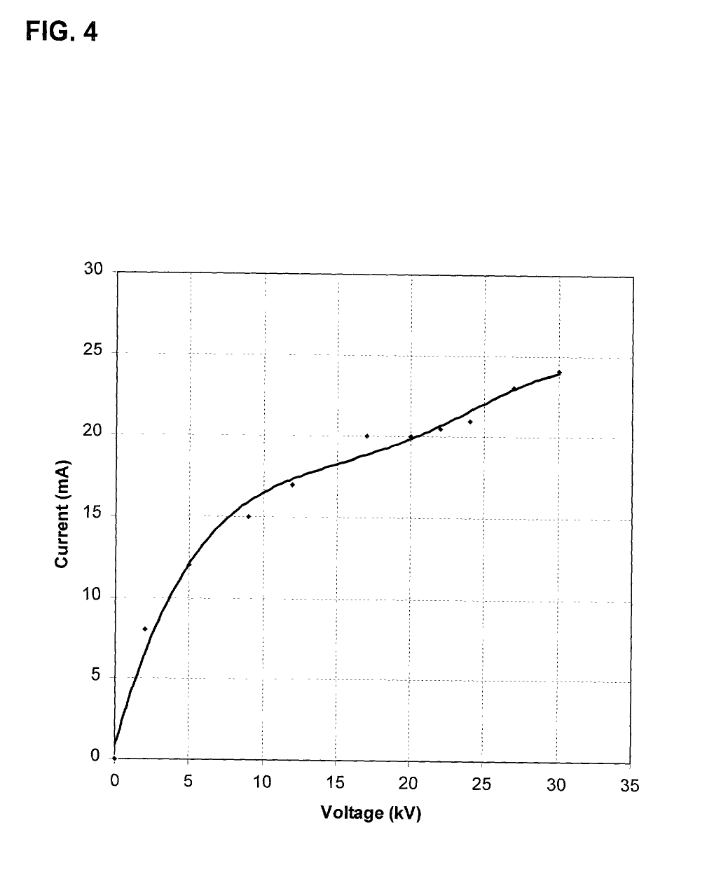

The first embodiment of the present invention uses a RF-ICP source. However, this requires a very low gas pressure, for example 0.1 mtorr and below. For higher ion dose implantation applications, a higher intensity plasma source is required. FIG. 3 shows schematically such an apparatus according to a second embodiment of the invention in which an electron cyclotron resonance (ECR) plasma source is used. In this embodiment of the invention the plasma is formed in a first part 20 of the vacuum chamber in a conventional manner. The wafer table 21 is located in a second part 22 of the vacuum chamber and the wafer table 21 may be negatively biased by means of a power supply 22. The second part 22 of the vacuum chamber is also provided with a pumping port 23. Importantly, the two parts 20,22 of the vacuum chamber communicate through an opening 24 (of a diameter d) provided in a wall 25 of the vacuum chamber that otherwise divides the two parts of the vacuum chamber. A conducting grid is provided across the opening 24 and the grid may be grounded with the walls of the vacuum chamber or may be negatively biased (though not as negative as the wafer stage). FIGS. 4 to 9 show the experimental results obtained in this embodiment of the present invention.

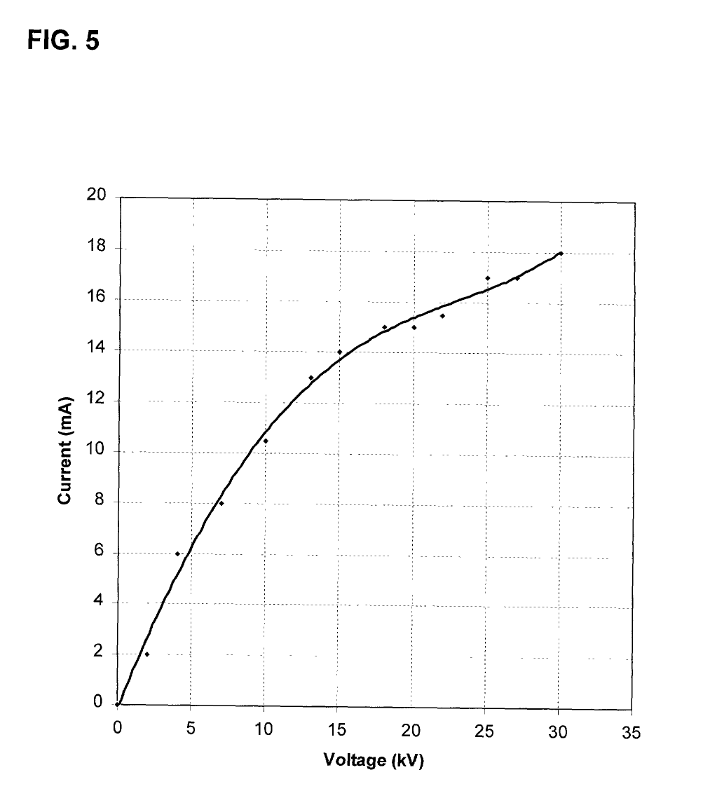

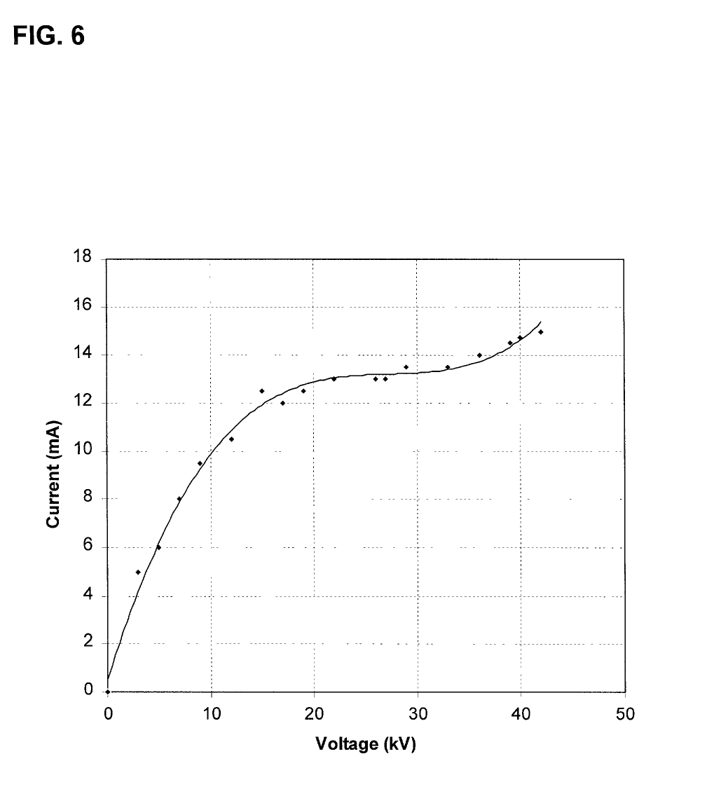

FIGS. 4 to 6 are I-V curves for respectively hydrogen, nitrogen and argon as a function of the bias voltage of the wafer stage. In FIG. 4 the hydrogen gas pressure is 6×10⁻⁵ torr, microwave input power is 250 W, base pressure is 3×10⁻⁶ torr, top magnetic coil current is 130A, bottom magnetic coil current is 125A, d=3.5 cm and the target is stainless steel. In FIG. 5 the nitrogen gas pressure is 4.3×10⁻⁵ torr, microwave input power is 750W, base pressure is 3×10⁻⁶ torr, top magnetic coil current is 126A, bottom magnetic coil current is 0A, d=3.5 cm and the target is stainless steel. In FIG. 6 the argon gas pressure is 4×10⁻⁵ torr, microwave input power is 750W, base pressure is 3×10⁻⁶ torr, top magnetic coil current is 125A, bottom magnetic coil current is 0A, d=3.5 cm and the target is stainless steel.

In this embodiment the plasma expands from the grid towards the target in the form of a beam. The area of the plasma sheath is almost constant with an increase in voltage which causes expansion of the sheath to the grid, but the density increases with voltage thus increasing the current rapidly with increasing voltage in a low voltage regime. As the voltage reaches a certain level, however, the plasma sheath reaches the grid.

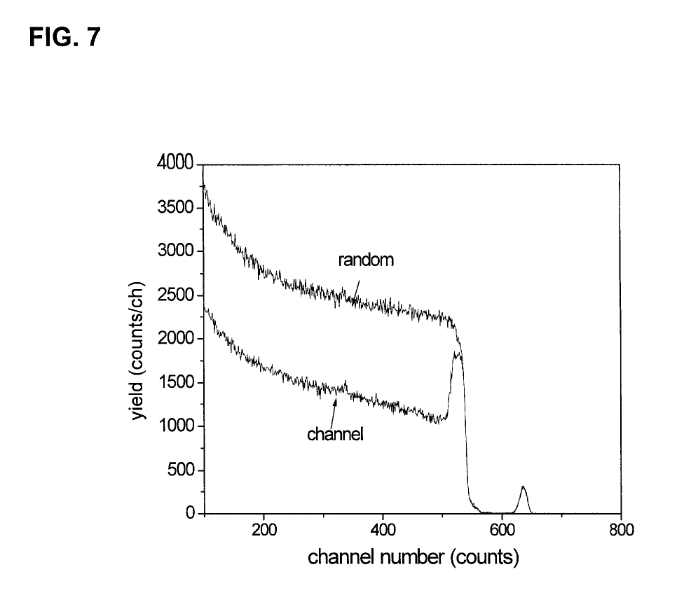

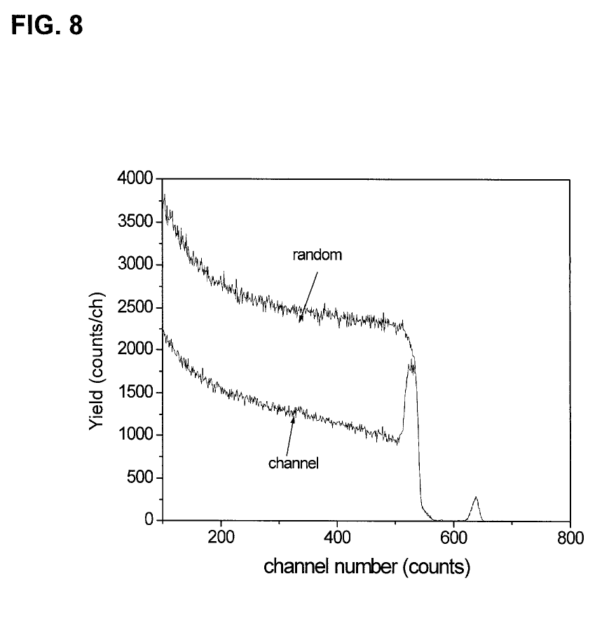

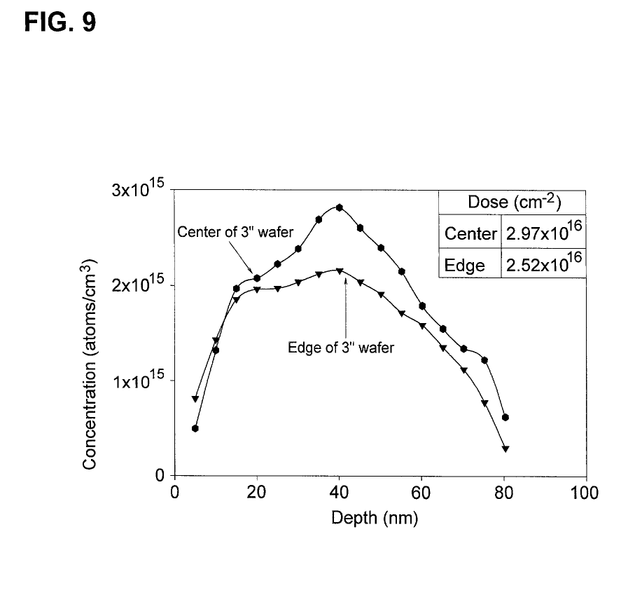

In order to further understand the energy distribution and dose uniformity of DC-PIII, RBS (Rutherford Backscattering Spectrometry) analysis was done for a 75 mm diameter silicon wafer implanted by DC-PIII. The implantation energy was 30 keV and implantation ion was argon. FIGS. 7 and 8 depict the results acquired from the center and side of the silicon wafer, respectively. The corresponding argon depth profiles are shown in FIG. 9. The argon depth profile of argon reveals that the ion energy is monoenergetic. The calculated doses at the center and side of the 75 mm wafer are 2.97×10 cm⁻² and 2.52×10¹⁶ cm⁻², respectively. The dose uniformity can be improved by using a more uniform plasma source and better chamber geometry. The results indicate that the dose rate and the electrical power efficacy are significantly improved by the DC-PIII of this embodiment of the present invention in comparison with the conventional PIII techniques of the prior art. For instance, the dose rate can be as high as 1×10¹⁷ cm⁻² min⁻¹, and the electrical power can be decreased to about one quarter of that in conventional pulse-mode PIII.

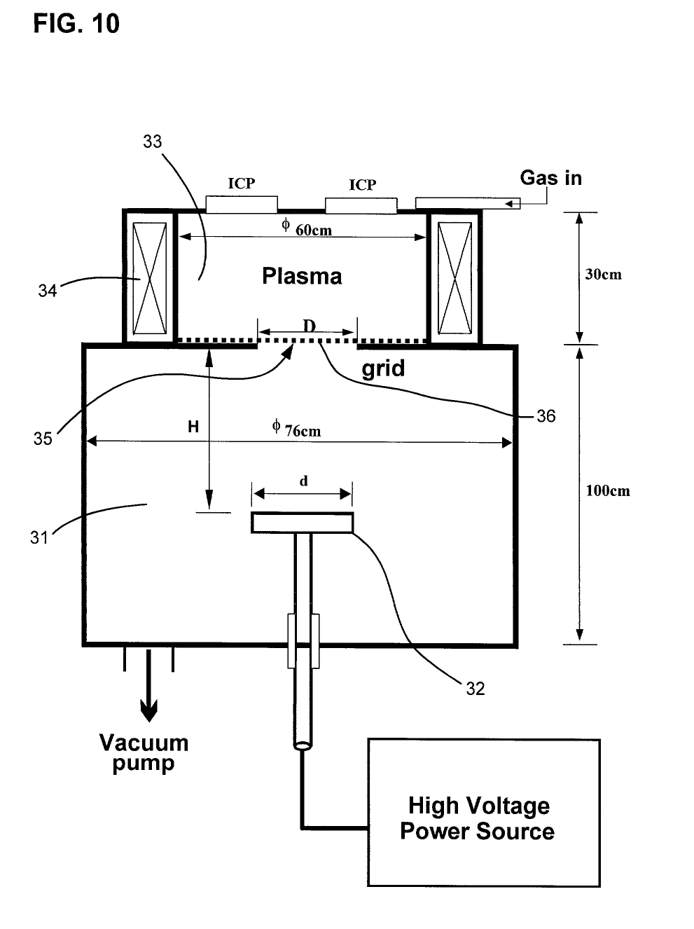

In the embodiments described above a DC PIII methodology is described. A further advantage of the apparatus of a preferred embodiment of the present invention, however, is that it may also permit long-pulse or quasi-DC PIII. In conventional PIII the typical voltage pulse duration is of the order of a few 10s of microseconds. The apparatus of this embodiment is shown in FIG. 10 and is capable of operating with long-pulses of the order of 100 to 500 microseconds or longer.

The apparatus of FIG. 10 is similar to the embodiment of FIG. 3 and includes a vacuum chamber divided into a lower part 31 in which is located the wafer stage 32, and an upper part 33 in which is formed the plasma (by RF-ICP). The upper part 33 is of a narrower width than the lower part 31, and the space formed by the step or shoulder formed between the two parts may be used to conveniently locate a magnetic coil 34 surrounding the upper part 33 of the chamber. The upper part 33 is formed with an inlet for the plasma forming gas, while the lower part 31 is formed with a connection to a vacuum pump. The wafer stage 32 may be connected to a high voltage power source so as to enable the wafer stage to be biased negatively.

The two parts 31,33 of the vacuum chamber communicate via a variable aperture 35 that allows plasma from the upper part 33 of the chamber to be extracted and accelerated towards the negatively biased wafer stage. Across the aperture 35 is formed a conducting grid 36 that is electrically grounded with the walls of the vacuum chamber. The size of the aperture may be varied so adjust the plasma beam size so as to match the diameter of the target. In this way the efficiency of the ion implantation may be enhanced.

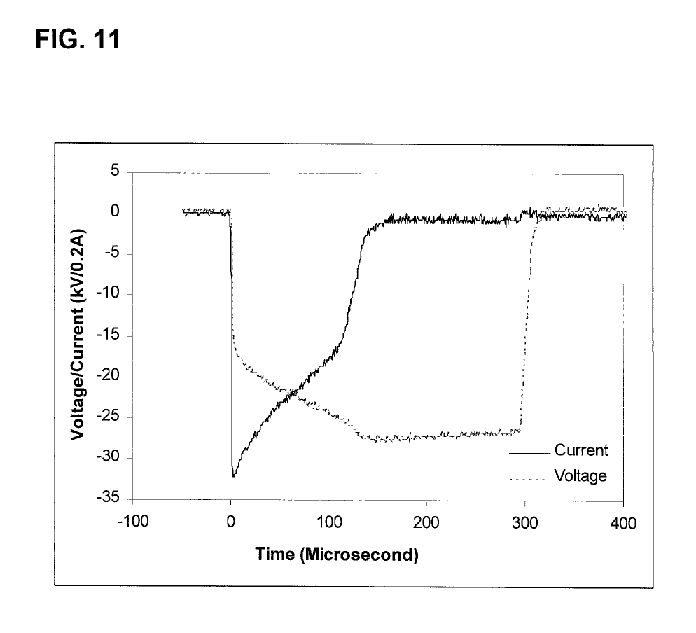

Typical voltage and current waveforms for this embodiment are shown in FIG. 11. The experimental conditions are: base pressure=3.3×10 Torr, hydrogen gas pressure=3.2×10⁻⁴ Torr, RF power=1 kW, magnetic field coil current=5 A, pulse frequency=50 Hz, H=25 cm, and D=25 cm. The voltage waveform shows a gradual increase in the beginning because the capacity of the high voltage modulator is not big enough. The current decreases rapidly between 120-150 μs, and the current stabilizes at a relatively small value after 150 μs. The current decreases gradually because the plasma sheath front arrives at the grid at 120 μs and the plasma sheath area reaches the extraction hole. Consequently, the current drops precipitously, and the plasma sheath is eventually stopped by the grounded conductive grid. The small constant current indicates that the system has evolved into a quasi-DC-PIII state. This may be confirmed by determining

The time when the plasma sheath reaches the grid may be determined by measuring the electron saturation current using a Langmuir probe. FIG. 12 shows the relationship between the pulse current and electron saturation current and the observation shows that a quasi-DC state exists. The plasma recovery time can also be determined by the Langmuir probe electron saturation current to determine the upper limit of the pulsing frequency. The plasma recovery time in the example conditions of this embodiment is about 800 μs. Therefore, the maximum pulse frequency is about 1 kHz.

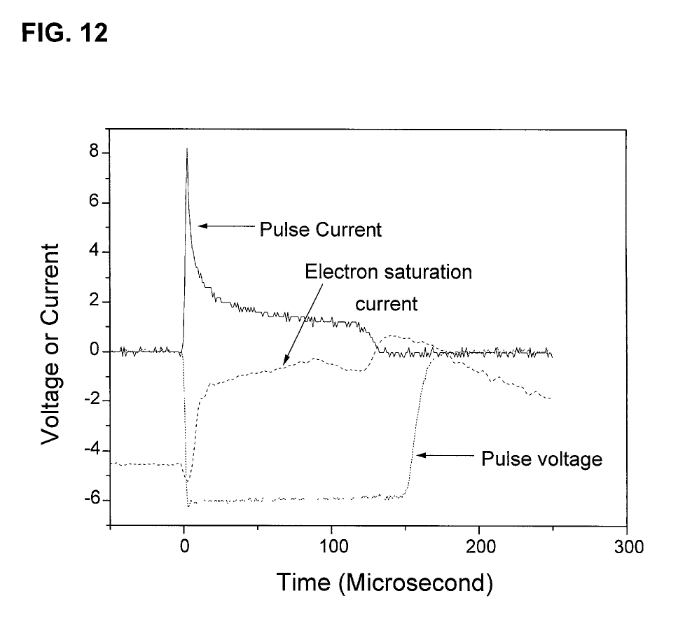

In this embodiment the implantation area can be changed by adjusting the instrumental parameters. FIG. 13 shows the optical micrograph of a 100 mm diameter silicon wafer after long-pulse hydrogen PIII and annealing at 650° C. for 30 minutes. The experimental conditions are: D=15 cm, H=37 cm, hydrogen gas pressure=5.5×10⁻⁴ Torr, RF power=1 kW, pulse voltage=−30 kV, pulse width=200 μs, pulsing frequency=125 Hz, and implantation time=20 minutes. It can be seen that an area in the center of the wafer extending to more than half of the radius shows surface blistering due to coalescence of underlying hydrogen microcavities, indicating that this region has been implanted with a higher dose. The implantation area can be controlled by adjusting D and H.

To demonstrate the improvement of surface hydrogen using long-pulse PIII of this embodiment of the present invention, samples implanted using 10 μs, 60 μs, and 300 μs are analyzed by high depth resolution SIMS, and the results are exhibited in FIG. 14. It can be observed that the amount of surface hydrogen can be reduced with longer pulse durations. In order to compare the results, the total hydrogen dose, D_{T}, the surface dose S_{H}(<40 nm), and the ratios of S_{H}/D_{T} are computed from the SIMS data and displayed in Table 1. The surface hydrogen ratio of the 300 μs sample is only half of that of the 10 μs sample.

TABLE 1
Total doses, surface doses, and ratios of the surface dose to the
total dose for the samples shown in FIG. 14.

| | | Surface Dose S_{H}(<40 nm) | |
|---|---|---|---|
| Sample | Total Dose D_{T}(cm⁻²) | (cm⁻²) | S_{H}/D_{T} |
| 10 μs | 1.04 × 10¹⁷ | 6.36 × 10¹⁶ | 61.15% |
| 60 μs | 1.13 × 10¹⁷ | 5.04 × 10¹⁶ | 44.60% |
| 300 μs | 1.19 × 10¹⁷ | 3.74 × 10¹⁶ | 31.43% |

In recapitulation, long-pulse Pill introduces a number of significant advantages compared to conventional short-pulse PIII. The practical pulse width can reach 500 μs or longer because the grid stops the expansion of the plasma sheath. Therefore, the dimensions of the vacuum chamber are not a limiting factor in long-pulse PIII experiments. The calculated maximum pulsing frequency is about 1 kHz that is limited by the plasma recovery time. A more reasonable and practical pulse width is about 100-500 μs. Results indicate that the ion energy distribution is improved and quasi-DC-PIII is observed in long-pulse PIII. In addition, the implanted area can be controlled by varying the location of the grid and ions mainly impact the surface of the silicon wafers thereby reducing sputtered contaminations and other undesirable effects. A further advantage of using long-pulse quasi-DC techniques is that the implantation dose can be controlled by varying the pulse duration and frequency.

It will be seen that the present invention, at least in its preferred forms, provides substantial advantages over the prior art. In particular the provision of a conducting grid located between the plasma and the target enables long-pulse or even steady-state DC operation as it is possible to at least delay and at best prevent completely the extinction of the plasma.

1. Apparatus for direct current plasma ion implantation, comprising:
(a) a vacuum chamber,
(b) an ion/plasma source
(c) means for supporting a target in said chamber,
(d) means for applying an electrical potential to said target supporting means, and
(e) a conducting grid being located between said target supporting means and said ion/plasma source dividing said chamber into two parts.

2. Apparatus as claimed in claim 1 wherein said conducting grid is grounded and said target supporting means is maintained at a negative potential.

3. Apparatus as claimed in claim 1 wherein said conducting grid is maintained at a positive or negative potential.

4. Apparatus as claimed in claim 1 wherein said vacuum chamber has a disk-like shape.

5. Apparatus as claimed in claim 4 wherein the dimensions of the chamber have the ratio r:R:H:D=1:4:2.5:2 where:
r=radius of the target
R=radius of the vacuum chamber
H=the distance between the target and the grid, and
D=the thickness of the target.

6. Apparatus as claimed in claim 1 wherein the grid is made of a material compatible with an intended target.

7. Apparatus as claimed in claim 6 wherein the intended target is a silicon wafer and the grid is made of a silicon mesh.

8. Apparatus as claimed in claim 1 wherein means are provided for varying the distance between the target supporting means and the conducting grid.

9. Apparatus as claimed in claim 1 wherein said vacuum chamber is divided into said two parts by a wall of said chamber, said wall being provided with an aperture allowing plasma formed in a first of said two part to diffuse into the second of said two parts containing said target, and wherein said conducting grid is provided across said aperture.

10. Apparatus as claimed in claim 9 wherein said aperture has a variable size.

11. Apparatus as claimed in claim 1 wherein said ion/plasma source is a radio-frequency inductively-coupled plasma source.

12. Apparatus as claimed in claim 1 wherein said ion/plasma source is an electron cyclotron resonance plasma source.

13. A method of plasma immersion ion implantation, comprising:
(a) providing on a supporting means within a vacuum chamber a target to be implanted,
(b) providing an ion/plasma source to said chamber,
(c) providing a conducting grid extending across said chamber and being located between said target and said ion/plasma source,
(d) maintaining a low pressure plasma in a space defined between said source and said grid, and
(e) maintaining said target supporting means at an electrical potential negative relative to said grid.

14. A method as claimed in claim 13 wherein said grid is maintained at a ground potential.

15. A method as claimed in claim 13 wherein said conducting grid is maintained at a first negative potential and said target supporting means is maintained at a second negative potential, said wafer stage being maintained at a negative potential relative to said conducting grid.

16. A method as claimed in claim 13 wherein said method is a DC method in which a continuous ion current is established between said grid and said target.

17. A method as claimed in claim 13 wherein said method is a long-pulse method in which said target is provided with a negative potential for long pulses.

18. A method as claimed in claim 17 wherein said pulses have a duration of from 100 μs to 500 μs.
